(19) United States
(12) Patent Application Publication
(10) Pub. No.: US 2024/0170348 A1
(43) Pub. Date: May 23, 2024

(54) SYSTEM AND METHOD FOR AUTOMATIC WAFER MAP CLASSIFICATION

(71) Applicant: Optimal Plus Ltd., Holon (IL)

(72) Inventors: Ofir Suranyi, Be'er Ya'akov (IL); Miriam Horovicz, Bnei Brack (IL); Alberto Alexis Jeno, Pleasant Hill, CA (US)

(73) Assignee: Optimal Plus Ltd., Holon (IL)

(21) Appl. No.: 18/514,271

(22) Filed: Nov. 20, 2023

Related U.S. Application Data
(60) Provisional application No. 63/426,952, filed on Nov. 21, 2022.

(51) Int. Cl. H01L 21/66; G06T 7/00

(52) U.S. Cl. CPC H01L 22/24; G06T 7/0004; G06T 2207/30148

(57) ABSTRACT

A method of testing semiconductor wafers includes receiving a wafer bin map for a semiconductor wafer, wherein the wafer bin map includes a plurality of points corresponding to a plurality of defective dies fabricated on the semiconductor wafer, identifying a cluster of points in the wafer bin map from the plurality of points, and generating a filtered bin map using the cluster of points. The method also includes extracting a set of features for the filtered bin map, wherein the set of features comprises a set of global features common to the semiconductor wafer and a set of cluster features specific to the filtered bin map, executing a trained machine learning model using the set of features as inputs to generate a pattern classification, and determining, based on the pattern classification, that the semiconductor wafer includes a pattern of defective dies caused by a defective manufacturing process.

### CROSS-REFERENCES TO RELATED APPLICATIONS

This application claims the benefit of U.S. Provisional Patent Application No. 63/426,952, filed Nov. 21, 2022, entitled “SYSTEM AND METHOD FOR AUTOMATIC WAFER MAP CLASSIFICATION,” the disclosure of which is incorporated hereby incorporated by reference for all purposes.

### BACKGROUND

During semiconductor production, wafer maps are obtained by testing each die on a wafer. Wafer maps may reveal one or more patterns of defective dies caused as a result of one or more manufacturing processes. Despite progress made in the area of improving semiconductor manufacturing, there is a need for more expeditious and efficient methods and systems for classifying wafers maps.

### SUMMARY

According to an embodiment of the present invention, a method of testing semiconductor wafers is provided. The method includes receiving a wafer bin map for a semiconductor wafer, wherein the wafer bin map includes a plurality of points corresponding to a plurality of defective dies fabricated on the semiconductor wafer, and identifying a cluster of points in the wafer bin map from the plurality of points that correspond to a cluster of defective dies on the semiconductor wafer. The method also includes generating a filtered bin map using the cluster of points, extracting a set of features for the filtered bin map, wherein the set of features comprises a set of global features common to the semiconductor wafer and a set of cluster features specific to the filtered bin map, executing a trained machine learning model using the set of features as inputs to generate a pattern classification for the semiconductor wafer, and determining, based on the pattern classification, that the semiconductor wafer includes a pattern of defective dies caused by a defective manufacturing process used to manufacture the semiconductor wafer.

According to another embodiment of the present invention, a semiconductor manufacturing system is provided. The semiconductor manufacturing system includes a wafer classification system, wherein the wafer classification system comprises a memory; and one or more hardware processors that, when executing computer executable instructions stored in the memory, are configured to: receive a wafer bin map for a semiconductor wafer, wherein the wafer bin map includes a plurality of points corresponding to a plurality of defective dies fabricated on the semiconductor wafer; identify a cluster of points in the wafer bin map from the plurality of points that correspond to a cluster of defective dies on the semiconductor wafer; generate a filtered bin map using the cluster of points; extract a set of features for the filtered bin map, wherein the set of features comprises a set of global features common to the semiconductor wafer and a set of cluster features specific to the filtered bin map; execute a trained machine learning model using the set of features as inputs to generate a pattern classification for the semiconductor wafer; and determine, based on the pattern classification, that the semiconductor wafer includes a pattern of defective dies caused by a defective manufacturing process used to manufacture the semiconductor wafer.

According to a particular embodiment of the present invention, a non-transitory processor-readable medium for testing semiconductor wafers is provided. The non-transitory processor-readable medium for testing semiconductor wafers includes processor-readable instructions configured to cause one or more processors of a wafer classification system to: receive a wafer bin map for a semiconductor wafer, wherein the wafer bin map includes a plurality of points corresponding to a plurality of defective dies fabricated on the semiconductor wafer; identify a cluster of points in the wafer bin map from the plurality of points that correspond to a cluster of defective dies on the semiconductor wafer; generate a filtered bin map using the cluster of points; extract a set of features for the filtered bin map, wherein the set of features comprises a set of global features common to the semiconductor wafer and a set of cluster features specific to the filtered bin map; execute a trained machine learning model using the set of features as inputs to generate a pattern classification for the semiconductor wafer; and determine, based on the pattern classification, that the semiconductor wafer includes a pattern of defective dies caused by a defective manufacturing process used to manufacture the semiconductor wafer.

### BRIEF DESCRIPTION OF THE DRAWINGS

The accompanying drawings, which are included to provide a further understanding of the disclosure, are incorporated in and constitute a part of this specification, illustrate embodiments of the disclosure and together with the detailed description serve to explain the principles of the disclosure. No attempt is made to show structural details of the disclosure in more detail than may be necessary for a fundamental understanding of the disclosure and various ways in which it may be practiced.

FIG. 1 illustrates a processing framework for wafer bin map classification according to some embodiments.

FIG. 2 illustrates an exemplary graphical representation of a wafer bin map according to some embodiments.

FIG. 3 illustrates exemplary graphical representations of wafer bin map patterns according to some embodiments.

FIG. 4 illustrates an exemplary transformation 400 from a wafer bin map to a filtered wafer bin map according to some embodiments.

FIG. 5 illustrates an exemplary mapping from a wafer bin map to wafer zones according to some embodiments.

FIG. 6 illustrates an exemplary mapping from a filtered wafer bin map to a circular zone distribution according to some embodiments.

FIG. 7 illustrates an exemplary method of identifying defect patterns on a semiconductor wafer according to some embodiments.

FIG. 8 illustrates an exemplary method of testing electronic components according to some embodiments.

FIG. 9 illustrates a block diagram of an embodiment of a computer system according to some embodiments.

### DETAILED DESCRIPTION

The ensuing description provides preferred exemplary embodiment(s) only, and is not intended to limit the scope, applicability, or configuration of the disclosure. Rather, the ensuing description of the preferred exemplary embodiment(s) will provide those skilled in the art with an enabling description for implementing a preferred exemplary embodiment. It is understood that various changes may be made in the function and arrangement of elements without departing from the spirit and scope as set forth in the appended claims.

Certain embodiments relate to systems and methods for automatic wafer map classification. During semiconductor production, a plurality of dies are manufactured on a single wafer. For each wafer, all, or a subset, of the dies on the wafer may be tested against one or more threshold criterion, to determine if the tested die meets specifications and/or is not an outlier with respect to other dies on the wafer, or other dies in a lot of wafers. Based on the testing, dies that meet the one or more threshold criterion may be assigned to one or more passing bins while the defective dies may be assigned to a failing bin.

Based on the location of the dies on a wafer, and their assigned bins, a wafer bin map (WBM) can be constructed to visualize, or otherwise track, the relative locations of passing and defective dies on a wafer. WBMs may reveal one or more patterns of defective dies caused as a result of one or more manufacturing processes, the machines used to manufacture the wafers, or the like. Based on the patterns, a particular manufacturing process and/or machine, may be identified as the most likely cause of the defective dies within a pattern. Once identified, the manufacturing process can be adjusted, or maintenance can be performed on a particular tool, to reduce the number of defective dies in future wafers, thereby improving the product quality.

Patterns identified in WBMs may further be used to augment component testing, binning, and/or pairing. For example, based on the location, or area, of a pattern of defective dies on a wafer, additional component tests may be performed on passing dies within the region of the pattern. Additionally, or alternatively, passing dies within the region of a pattern may be re-binned to indicate a higher likelihood of diminished quality associated with the passing dies.

While these, and other benefits may be derived from identifying patterns of defective dies from WBMs, existing techniques for identifying or classifying patterns of defective dies are often inaccurate, inefficient, cost prohibitive, and/or are not well integrated into the existing manufacturing, testing, and binning processes. These and other challenges may advantageously be overcome by applying an automatic classification framework to each WBM as it is manufactured and tested. For example, WBMs may be simplified using a clustering analysis. Features may be extracted from simplified WBMs. The features may include global features and local features. Global features may represent data common to a wafer, its corresponding WBM, and/or the set of dies included on the wafer. Local features may represent data specific to a cluster of dies and/or a zone of dies on the wafer. Using features extracted from a set of wafers, a machine learning (ML) model may be trained to classify patterns exhibited in WBMs. Subsequent WBMs may then be classified using the trained ML model to identify dies for special processing and/or defects in the manufacturing process.

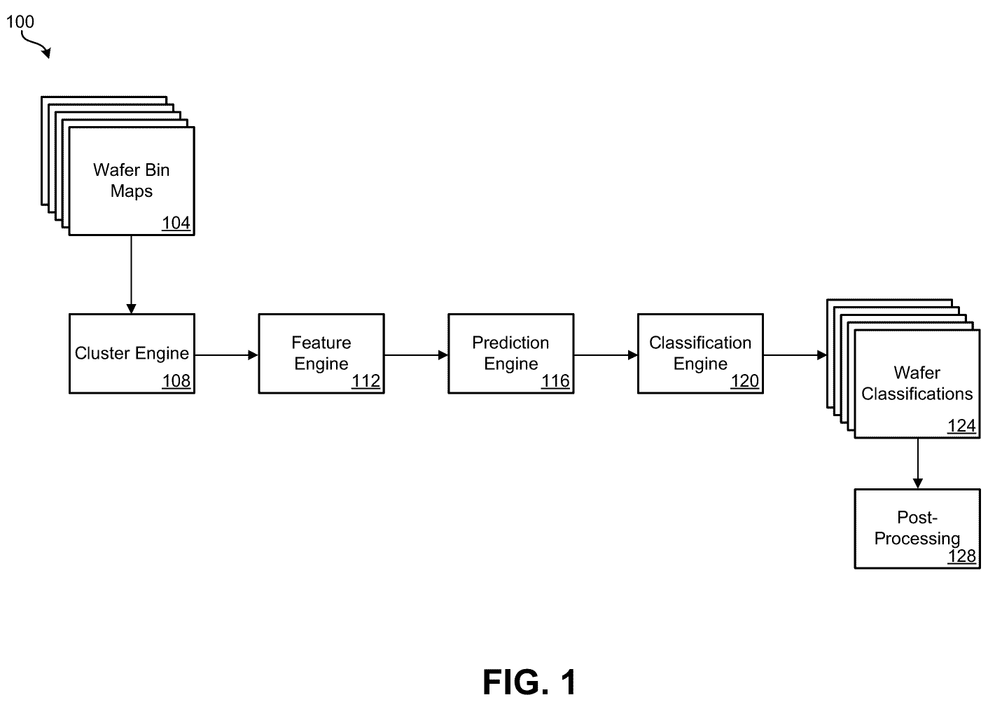

FIG. 1 illustrates a processing framework 100 for wafer bin map classification according to some embodiments. Processing framework 100 may include one or more hardware and/or software components configured to classify WBM patterns. For example, processing framework 100 may include: cluster engine 108; feature engine 112; prediction engine 116; classification engine 120; and post-processing 128. One or more of the components of processing framework 100 may be implemented as standalone and/or integrated software applications executable on one or more computer systems. For example, processing framework 100 may be implemented, or otherwise installed on a central or distributed server system as a WBM classification service accessible via one or more wired and/or wireless network connections.

The components and/or services of processing framework 100 may be remotely accessible from one or more manufacturing and testing facilities. For example, processing framework 100 may be located at a semiconductor manufacturer's headquarters and/or at a remote data processing center operated by the semiconductor manufacturer. The manufacturing and testing facilities may then transmit and receive data via one or more internet and/or intranet connections with processing framework 100.

Additionally, or alternatively, one or more components of processing framework 100 may be executed on a local computer system at a manufacturing and/or testing facility. For example, processing framework 100 may be installed on a workstation computer, such as a desktop or laptop computer, with access to manufacturing and testing data for the facility. As another example, processing framework 100 may be integrated into one or more manufacturing or testing machines and/or controllers such that, as a test tool captures test results for a wafer, the test controller can perform the WBM pattern classification in real-time. Based on the real-time classification, the test controller may allocate additional testing resources to wafers and/or dies to ensure high product quality. Additionally, or alternatively, the test controller may provide the results of the classification to a binning controller for evaluation when assigning dies to one or more bins.

As described above, processing framework 100 may receive WBMs 104 from one or more sources, such as a test tool, a test controller, a testing database at a manufacturing and/or testing facility, or the like. WBMs 104 may represent the quality and characteristics of individual dies or chips on a semiconductor wafer. WBMs 104 may include testing data and/or results in one or more types of formats. For example, WBMs 104 may include tabular data structures identifying each individual die on a wafer, the location of the die on the wafer, and one or more test results associated with each die. The location of the die may be represented using grid or matrix coordinates, such as the column and row indices for each die on a wafer. The test results may indicate one or more results of testing each die, such as a passing or failing status, whether a die meets one or more predefined threshold criteria, or the like. Additionally, or alternatively, WBMs 104 may be visualized using one or more graphical representations.

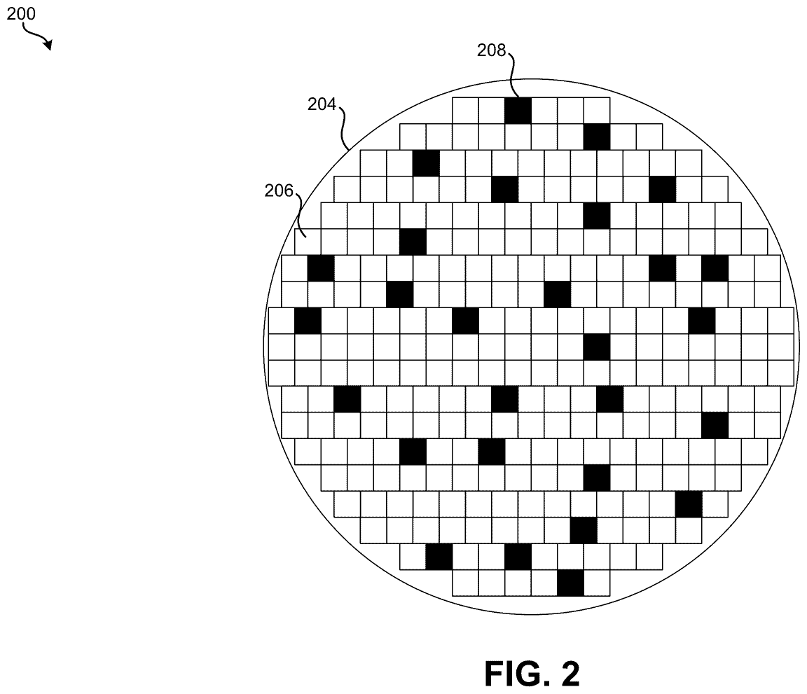

FIG. 2 illustrates an exemplary graphical representation 200 of a wafer bin map according to some embodiments. As illustrated, representation 200 depicts a top-down view of a semiconductor wafer 204, upon which a plurality of dies 206, represented by each individual square, have been manufactured. A subset of the plurality of dies 206 may be identified as defective dies in a WBM, illustrated as solid black squares in representation 200. As described above, representation 200 may be generated from a tabular representation of a WBM. For example, defective die 208 may be highlighted in representation 200 identifying a failing die in table with a corresponding row index of ‘0’ and column index of ‘2’. While there are a number of defective dies in representation 200, the distribution of defective dies may not conform to any common pattern associated with a defective manufacturing process or tool. Instead, the distribution of defective dies may simply represent a normal or expected distribution of acceptable amounts of defective dies.

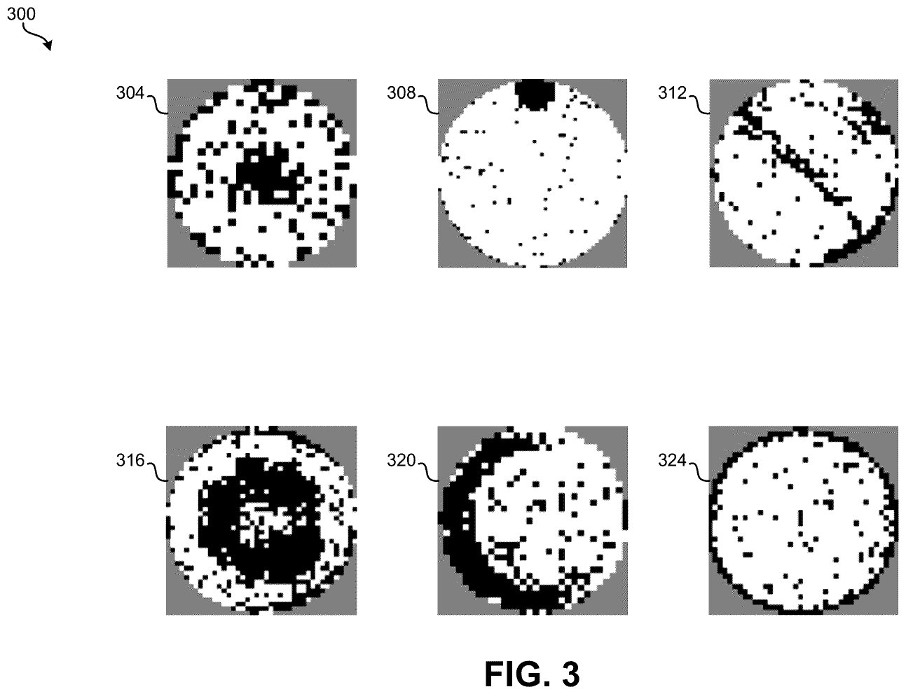

FIG. 3 illustrates exemplary graphical representations 300 of wafer bin map patterns according to some embodiments. As described above, the distribution of defective dies in WBMs often conform to one or more types of spatial patterns associated with defective manufacturing processes or tools, such as an Edge-Loc pattern, a Donut pattern, a Center pattern, a Loc pattern, an Edge Ring pattern, a scratch pattern, a random pattern, a “none” pattern, a pass, and the like. For example, first pattern representation 304 illustrates a center pattern in which a circular cluster of defective dies are concentrated near the center of the wafer. As another example, second pattern representation 308 illustrates a Loc pattern in which a cluster of defective dies are concentrated near an edge of the wafer. While illustrated at or near the center of a wafer and at or near the edge of a wafer, dense clusters of defective dies may be identified as a Loc pattern at other locations between the center and edge of the wafer.

As further illustrated, third pattern representation 312 depicts a scratch pattern including a linear distribution of defective dies extending from a top-left edge of the wafer, through the center, and to the bottom-right edge of the wafer. As yet another example, fourth pattern representation 316 illustrates a Donut pattern in which defective dies are distributed in a circular pattern around the center of the wafer with fewer defective dies being identified in the center of the wafer. Fifth pattern representation 320 illustrates an Edge-Loc pattern in which a dense distribution of defective dies near the edge of the wafer extends around a partial circumference of the wafer. Sixth pattern representation 324 illustrates an Edge-Ring pattern in which a majority of the dies at the edge of the wafer are defective. While not illustrated, additional types and/or combinations of patterns may be identifiable from WBMs.

Referring back to FIG. 1, WBMs 104 may initially be received and processed by cluster engine 108. As described above, cluster engine 108 may include one or more software applications, algorithms, or the like configured to simplify WBM data. Simplifying WBM data may include reducing or eliminating “noise” within the WBM data. As described above, WBM data may exhibit distributions of defective dies that conform to one or more types of defect patterns. However, WBM data may also include data associated with defective dies that are not a part of a defect pattern. These defective dies may be identified based on their distance from other defective dies and/or their distance from other clusters of defective dies that meet one or more predefined density criteria.

In some embodiments, cluster engine 108 uses one or more clustering analysis techniques to simplify WBM data prior to classification. The one or more clustering techniques may be applied to initial WBMs, to remove data from the WBMs that are unlikely to be associated with a defect pattern. The data removed from the WBMs may represent dies that failed during testing, but which do not belong to a cluster identified by a clustering analysis, or dies which belong to a cluster with properties of noise. Removing such data from the WBMs may result in simplified WBM data, referred to herein as a clean WBM and/or a filtered WBM, as referred to herein.

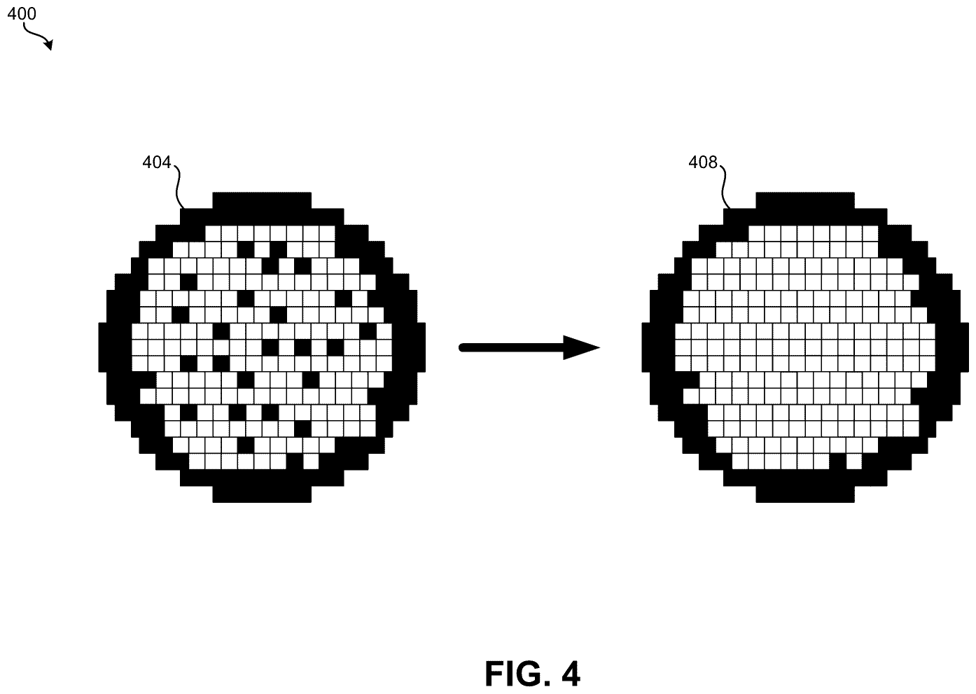

FIG. 4 illustrates an exemplary transformation 400 from a wafer bin map to a filtered wafer bin map according to some embodiments. As illustrated, WBM 404 includes a plurality of defective dies, represented by solid black boxes. As further illustrated by WBM 404, a majority subset of the plurality of defective dies are located at or near the edge of the wafer consistent with an Edge-Ring pattern, while the remaining defective dies are randomly distributed throughout the interior of the wafer. Using one or more clustering techniques, the randomly distributed defective dies may be identified as noise due to their distance and distribution relative to the distribution of defective dies surrounding the edge of the wafer. Filtered WBM 408 may be generated by removing the defective dies identified as noise in WBM 404.

While illustrated as graphical representations the transformation need not be visualized in such a way. Instead, entries in a tabular data structure may be modified and/or removed, to produce a filtered data structure representing the dies, and their associated locations, that belong to a cluster identified by a clustering analysis. Further, multiple tabular data structure may be produced from a single input, such as when multiple discrete clusters are identified in a WBM. In such a case, separate data structures may be generated including the information for each cluster of defective dies.

Referring back to FIG. 1, the one or more clustering analysis techniques used by cluster engine 108 to simplify WBM data may include a novel version of a Density-Based Spatial Clustering of Applications with Noise (DBSCAN) algorithm to produce simplified WBM data. For example, cluster engine 108 may use a self-adaptive DBSCAN (SADBSCAN) algorithm. In some embodiments, cluster engine 108 may use an SADBSCAN algorithm with predefined parameters, and/or predefined ranges of parameters, based on certain characteristics associated with a WBM being analyzed. For example, the SADBSCAN algorithm may be executed on predefined ranges and/or combinations of parameters for low yield wafers due to the inherently higher number of defective dies. By limiting the ranges of parameters, such as the possible epsilon and minimum sample values, the computational complexity associated with identifying optimal clustering parameters may be reduced, resulting in a more efficient and faster analysis of clusters. As described herein, low yield wafers may include wafers where the percentage of defective dies on the wafer is greater than 35%, 50%, 70% or another similarly suitable yield percentage.

After simplifying the data in WBMs 104, the clean, or filtered, WBM data may be provided to feature engine 112. As described above, feature engine 112 may include one or more software applications, algorithms, or the like configured to extract one or more sets of features for each WBM. The one or more sets of features may include global features and/or local features. Global features may represent characteristics common across an entire WBM. In other words, global features may be the same regardless of the number of clusters identified in a WBM and/or any individual characteristics of a particular cluster. For example, global features may include a cluster percentage feature representing the number of defective included in all clusters identified in a WBM divided by the total number of defective dies on the wafer. As another example, global features may include a total yield feature representing the number of defective dies on a wafer divided by the total number of dies on the wafer. Additional examples of global features may represent the average distance between a center of the wafer and a cluster centroid, the mean intra-cluster distance, one or more covariances, and/or degrees of linear correlation within the WBM.

Local features may describe data specific to each cluster identified in a WBM by cluster engine 108. Stated differently, local features may represent parameters of a cluster. Accordingly, for each WBM, multiple sets of local features may be extracted based on the number of clusters identified in the WBM. In some embodiments, the local features for each cluster describe data represented by particular zones or spatial regions of a WBM. Aggregating cluster data according to predefined zones or regions may reduce the computational complexity associated with training and executing a machine learning (ML) model to classify clusters of defective dies as one or more types of defect patterns.

In some embodiments, filtered WBMs are normalized prior to extracting global and/or local feature. Normalizing WBMs may include shifting the matrix of a WBM to a predefined origin and/or normalizing the size of the WBM to a predefined size (e.g., 10×10, 50×50, 100×100, etc). Filtered WBMs may be normalized to a standard defined for extracting a set of features for a classification ML model and/or based on the origin and/or size of the WBMs used to train a classification ML model.

In some embodiments, multiple zones are defined for a WBM with each zone representing a division, region, or area of the wafer represented by the filtered WBM. For example, WBMs may be divided into 3 zones, 5 zones, 7 zones, 10 zones, 13 zones, or more, with each zone representing a subset of the normalized WBM data. In other words, each zone may represent multiple defective dies in the underlying cluster identified in the WBM. In some embodiments, a circular distribution of zones is defined to simulate the physical and/or chemical processes that a wafer goes through during manufacturing.

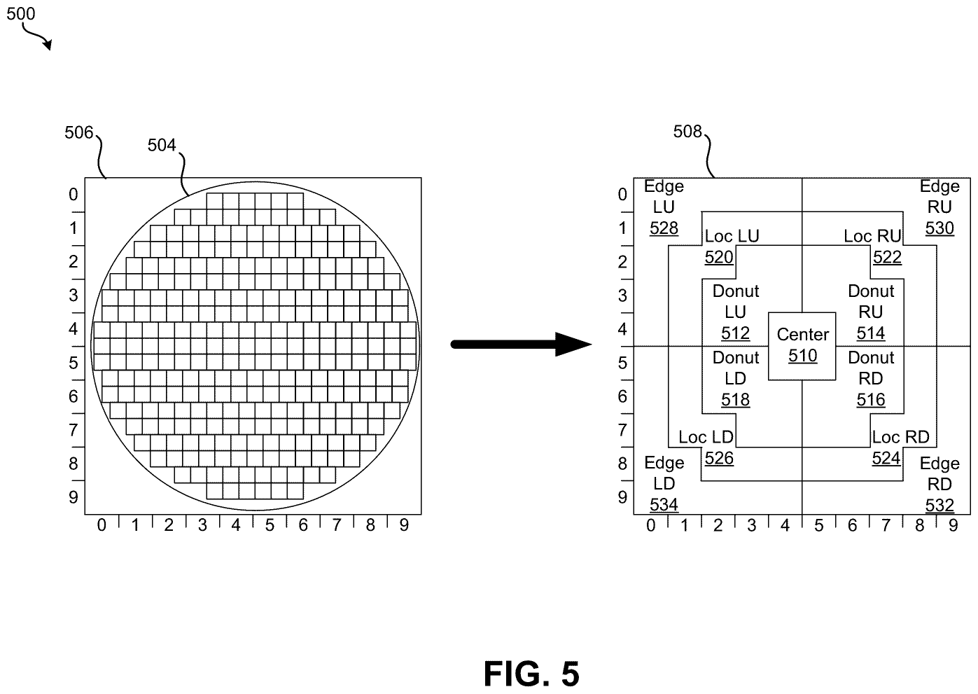

FIG. 5 illustrates an exemplary mapping 500 from a wafer bin map to wafer zones according to some embodiments. As illustrated, WBM 504 may include a plurality of dies, with each individual die being represented by a square. As further illustrated, WBM 504 may be normalized into a grid or matrix distribution, such as grid distribution 506, such that each subset of multiple dies on the wafer are represented by a corresponding cell in the grid. While illustrated as a 10×10 grid with 100 cells, WBM 504 may be normalized according to various types of distributions and/or dimensions, such as 20×20 grids, 50×50 grids, 100×100 grids, or the like.

As further illustrated, grid distribution 506 may further be transformed into circular zone distribution 508, with each zone representing the data for multiple cells in grid distribution 506. For example, center zone 510 may include the four center-most cells of grid distribution 506. Four “donut” zones may further be defined for each quadrant of 7 cells directly adjacent to center zone 510, including: Donut LU 512 corresponding to the left upper quadrant of cells; Donut RU 514 corresponding to the right upper quadrant; Donut RD 516 corresponding to the right lower quadrant; and Donut LD 518 corresponding to the left lower quadrant. Four “Loc” zones including Loc LU 520, Loc RU 522, Loc RD 524, and Loc LD 526 may be defined extending radially outward from the four donut zones, and four “Edge” zones including Edge LU 528, Edge RU 530, Edge RD 532, and Edge LD 534 may be defined extending radially outward from the Loc zones.

While illustrated and described as thirteen zones in a circular distribution, fewer or more zones distributed according to various types of patterns may similarly be defined as necessary to improve processing efficiency and/or classification accuracy. In some embodiments, the number and distribution of zones are based at least in part on the processes applied to a wafer during manufacturing and/or the defect patterns such processes may generate. In addition, while described in relation to the number of cells in grid distribution 506, the number of cells and/or dies represented by each zone may scale proportionally depending on the dimensions of the grid distribution and/or the distributions WBMs.

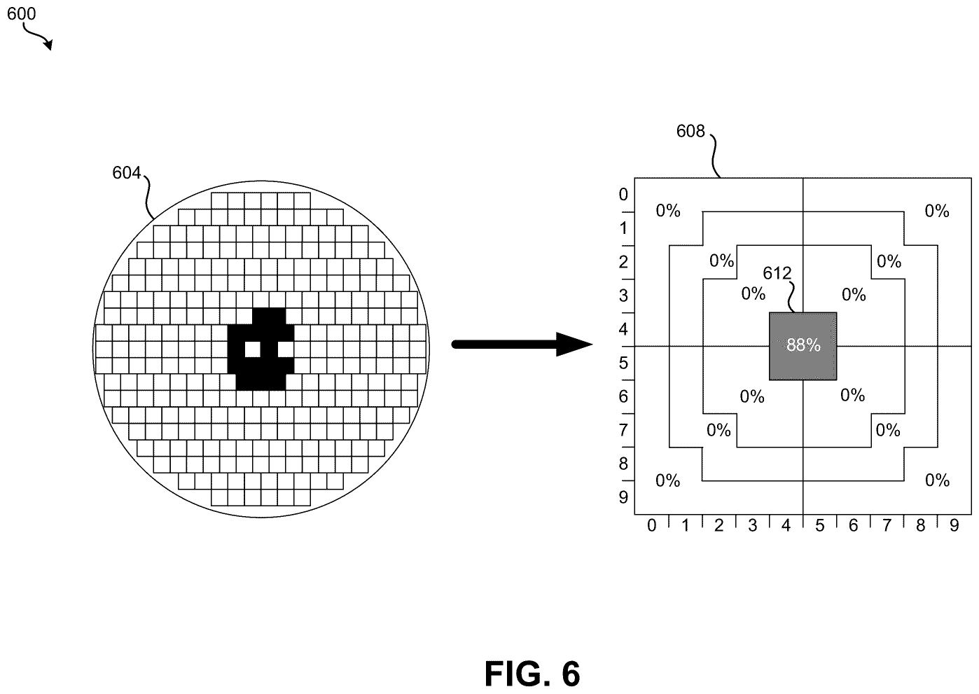

FIG. 6 illustrates an exemplary mapping 600 from a filtered wafer bin map to a circular zone distribution according to some embodiments. As illustrated, filtered WBM 604 includes a cluster of defective dies in the center of the wafer. As described above, the defective dies in the cluster may be attributed to one or more zones in a normalized distribution, such as circular zone distribution 608. Circular zone distribution 608 may be defined in the same or a similar fashion as described above in relation to circular zone distribution 508. As further illustrated, all of the defective dies in the cluster represented in filtered WBM 604 may be attributed to center zone 612. Attributing defective dies to a particular zone may include determining a number of defective dies in the cluster that are included in the particular zone. Additionally, or alternatively, the number of defective dies may be represented by a normalized percentage of defective dies in the zone to the total number of dies covered by the zone. For example, and as illustrated, the percentage of defective dies represented in center zone 612 may be 88%.

In some embodiments, the local features for each cluster may characterize the defective dies from the cluster that are located within each particular zone. For example, the local features for filtered WBM 604 may include a center zone feature with a value that corresponds to the number or percentage of defective dies represented by center zone 612 (e.g., 88%). Additional features may be defined for each of the remaining zones in circular zone distribution 608 (e.g., 0%). Additional local features may be defined for other characteristics of a zone, such as the average distance between defective dies in the zone.

Referring back to FIG. 1, feature engine 112 may extract a set of local features for each cluster identified in a WBM by cluster engine 108 as well as a set of global features the WBM that is common for each cluster identified in the WBM. As such, feature engine 112 may extract multiple sets of features for each WBM in WBMs 104. In some embodiments, the extracted features for each cluster, including the local features for the cluster and the global features for the WBM, are provided to classification engine 120.

Additionally, or alternatively, the WBM data, the filtered WBM, and/or the extracted features may be provided to prediction engine 116. As described above, prediction engine 116 may include one or more software applications, algorithms, or the like configured to apply one or more pre-model rules to the extracted features to generate a preliminary pattern classification.

For example, pre-model rules based on unique feature characteristics may be used to identify WBM classifications prior to execution of the ML model. Unique feature characteristics may include feature values meeting one or more predefined thresholds, such as a total yield above or below predefined maxima or minima values or the like. For example, a pre-model rule may be defined such that WBMs with a total yield exceeding 80%, 90%, 95%, or more, are classified as exhibiting a “clean” pattern while WBMs with total yields below 15%, 10%, 5%, or less, are classified as exhibiting a “near-full” pattern. Depending on the results of the pre-model rules, prediction engine 116 may make a final classification determination for a WBM, thereby avoiding unnecessary data processing by classification engine 120.

As described above, classification engine 120 may include one or more software applications, ML models, neural networks (NNs), or the like configured to receive, as inputs, the extracted features for a WBM and/or for an individual cluster identified on a WBM and generate a defect pattern classification. In some embodiments, features extracted from a plurality of WBMs with known defect patterns may be used to train a machine learning model to classify defect patterns in subsequent WBMs. In some embodiments, the machine learning model is a decision-tree-based ensemble ML algorithm that uses a gradient boosting framework. In some embodiments, each set of features extracted from the plurality of WBMs used to train the ML model are labeled with the classification represented by the set of features.

Once trained, the ML model may be executed on the global features extracted from a WBM of WBMs 104 and one or more sets of local features corresponding to the clusters identified in WBM by cluster engine 108, to produce wafer classifications 124. Wafer classifications 124 may indicate whether a wafer exhibits one or more defect patterns, such as an Edge-Loc pattern, a Donut pattern, a Center pattern, a Loc pattern, an Edge Ring pattern, a scratch pattern, a random pattern, a “none” pattern, a pass, or the like. In some embodiments, a wafer classification generated for a WBM includes one or more pattern classifications. Each pattern classification of the one or more pattern classifications for a particular WBM may correspond to a respective pattern type. For example, a wafer classification may include multiple classifications representing the probability and/or likelihood of the defective dies on a wafer exhibiting a respective type of pattern.

Wafer classifications 124 may be provided to post-processing 128. As described above, post-processing 128 may include one or more software applications, algorithms, or the like configured to determine appropriate remediation measures. In some embodiments, wafer classifications 124 are used to identify dies on a wafer for additional testing, verification, processing, and the like. For example, in response to classifying a WBM as exhibiting a first pattern, dies located within the pattern that otherwise passed an initial set of tests may be submitted for additional testing.

In some embodiments, wafer classifications 124 are used to identify defects in a manufacturing process and/or the machines used to manufacture the wafer and/or other wafers. For example, in response to classifying a WBM as exhibiting a second pattern, a particular machine, or component used to manufacture the corresponding wafer, may be identified and a maintenance course of action may be assigned to the identified machine. As another example, updated process parameters may be transmitted to one or more a manufacturing tools that perform the manufacturing process that resulted in the second pattern.

Additionally, or alternatively, one or more binning assignments for a wafer may be modified based on wafer classifications 124. For example, in response to classifying a WBM as exhibiting a particular defect patter, binning assignments for dies located within the defect pattern that otherwise passed an initial set of tests may be updated, and/or a command may be transmitted to a binning machine, to bin the dies in a bin corresponding to a reduced product quality.

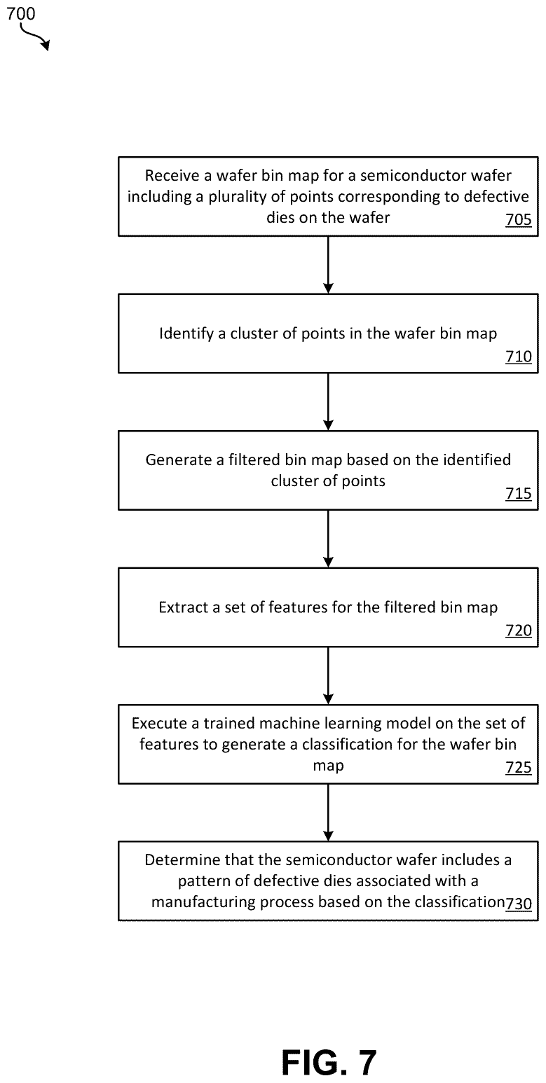

Various methods may be performed using the processing framework detailed in relation to FIGS. 1-6. FIG. 7 illustrates an exemplary method 700 of identifying defect patterns on a semiconductor wafer according to some embodiments. Method 700 may be performed by one or more components of an automatic wafer bin map classification framework, such as processing framework 100 as described above. For example, one or more software applications executing on a central or distributed server system may perform some or all of method 700. At block 705, a wafer bin map for a semiconductor wafer is received. The wafer bin map may include a plurality of points corresponding to defective dies on the semiconductor wafer. The defective dies may be identified by one or more test procedures applied during and/or after manufacturing of each die on the semiconductor wafer. The defective dies may be identified by their respective test results, such as passing or failing test result. The wafer bin map may identify each unique die on the semiconductor wafer, their relative location on the semiconductor wafer, and their test result status and/or binning status. The wafer bin map may be received in a tabular or matrix format and/or a graphical representation, as described above.

At block 710, a cluster of points in the wafer bin map are identified. The cluster of points may represent a subset of the plurality of points that correspond to defective dies. The cluster of points may be identified by applying one or more clustering analysis techniques to the plurality of points that correspond to defective dies. For example, using the plurality of points that correspond to defective dies, and their respective locations, a clustering algorithm may identify one or more clusters of points, or defective dies, where the distance between each point within the cluster meets one or more predefined threshold distance or proximity criteria, and/or where the density of the points in the cluster meets one or more predefined density criteria. In some embodiments, applying the one or more clustering analysis techniques includes applying an SADBSCAN algorithm to the plurality of points in the wafer bin map that correspond to defective dies on the semiconductor wafer.

In some embodiments, the one or more clustering analysis techniques identify one or more distinct clusters of points in the wafer bin map. Each cluster may represent a potential defect pattern exhibited by the semiconductor wafer. In some embodiments, the one or more clustering analysis techniques identify a second subset of the plurality of points that correspond to noise in the wafer bin map. In other words, the points in the second subset may correspond to defective dies in the wafer bin map that are not within a predefined distance to other defective dies and/or are part of a cluster with a density less than a predefined cluster density threshold.

At block 715, a filtered bin map is generated based on the identified cluster of points. The filtered bin map may be a simplified representation of the wafer bin map in which points that are not part of the cluster identified in block 710 are not included. In other words, the filtered bin map may be generated by removing the second subset of points that correspond to noise from the wafer bin map. In some embodiments, multiple filtered bin maps are generated for a single wafer bin map. For example, in the event that multiple clusters are identified at block 710, a unique filtered bin map may be generated for each cluster that is not identified as representing noise. Additionally, or alternatively, the filtered bin map may include multiple subsets of points of the plurality of points that correspond to the multiple clusters identified at block 710. In other words, the filtered bin map may be generated by removing only the points that correspond to noise from the wafer bin map.

At block 720, a set of features for the filtered bin map are extracted. The set of features may include global features common to the semiconductor wafer and/or wafer bin map, as well as local and/or cluster features specific to the filtered bin map and/or an individual cluster in the filtered bin map. The global features may represent information about defective dies relative to the semiconductor wafer as a whole, such as the total yield of the semiconductor wafer. Additionally, or alternatively, the global features may represent information about defective dies in the filtered bin map relative to the semiconductor wafer, or wafer bin map, such as the percentage of total defective dies in the wafer bin map that are included in the filtered bin map and/or a cluster identified at block 710.

The local features may represent information about the defective dies included in the one or more clusters identified at block 710, such as the number or percentage of bad dies in the cluster that are within a particular region or area of the semiconductor wafer. In some embodiments, the dimensions of the wafer bin map are normalized to one or more predefined wafer map distributions, such as a 10×10 grid or a 100×100 grid, wherein each cell in the normalized map corresponds to a region or collection of coordinates in the wafer bin map. In some embodiments, the normalized map is further separated into a subset of zones. The subset of zones may conform to a circular distribution, as described above, centered around the central coordinates of the wafer bin map. For each zone, one or more zone or local features may be extracted, such as the number of defective dies in the filtered bin map and/or within a single cluster of the filtered bin map that are located within the respective zone.

To illustrated, given a filtered bin map with a cluster of 20 points corresponding to defective dies distributed in the shape of an annulus around the center of a semiconductor wafer, each quarter of the points may be attributed to a corresponding zone in a circular distribution that includes thirteen zones. As a result, the local features extracted for the filtered bin map may include four zone features that each represent a quarter of the 20 points, and the remaining 9 zone features represent no points. While described as representing the number of points within a zone, zone features may additionally or alternatively represent one or more statistical values associated with the defective dies attributed to the zone, such as the percentage of total dies within the zone that are defective, the percentage of defective dies in the filtered bin map that are within the zone, or the like.

At block 725, a trained machine learning model is executed on the set of features to generate a classification for the wafer bin map. As described above, the machine learning model may be trained on sets of features extracted from previously labeled wafer bin maps. For example, each wafer bin map used for training may include a label indicating a type of defect pattern exhibited by the corresponding semiconductor wafer, such as a center pattern, a donut pattern, a Loc pattern, an Edge-Ring pattern, or the like. In some embodiments, the model is capable of producing binary classifications for each type of defect pattern. For example, the classification may indicate whether the wafer bin map does or does not include each particular defect pattern. Additionally, or alternatively, the model may generate multi-class classifications. The model may support probabilistic classifications, offering confidence scores or probabilities associated with each class assignment. The probabilistic calculations may be used to evaluate the model's level of certainty.

At block 730, a determination is made that the semiconductor wafer includes a pattern of defective dies associated with a manufacturing process based on the classification. The determination may be made based on probabilities associated with each potential pattern classification. For example, given probabilities for each of a plurality of possible defect patterns, it may be determined that the semiconductor includes the one or more defect patterns with associated probabilities that exceed one or more predefined threshold criteria. In some embodiments, based on the determined pattern, a manufacturing process that is most likely to cause the defect pattern may be identified for remediation. Additionally, or alternatively, additional dies located within the defect pattern may be identified for further testing and analysis.

It should be appreciated that the specific steps illustrated in FIG. 7 provide a particular method of identifying defect patterns on a semiconductor wafer according to an embodiment of the present invention. Other sequences of steps may also be performed according to alternative embodiments. For example, alternative embodiments of the present invention may perform the steps outlined above in a different order. Moreover, the individual steps illustrated in FIG. 7 may include multiple sub-steps that may be performed in various sequences as appropriate to the individual step. Furthermore, additional steps may be added or removed depending on the particular applications. One of ordinary skill in the art would recognize many variations, modifications, and alternatives.

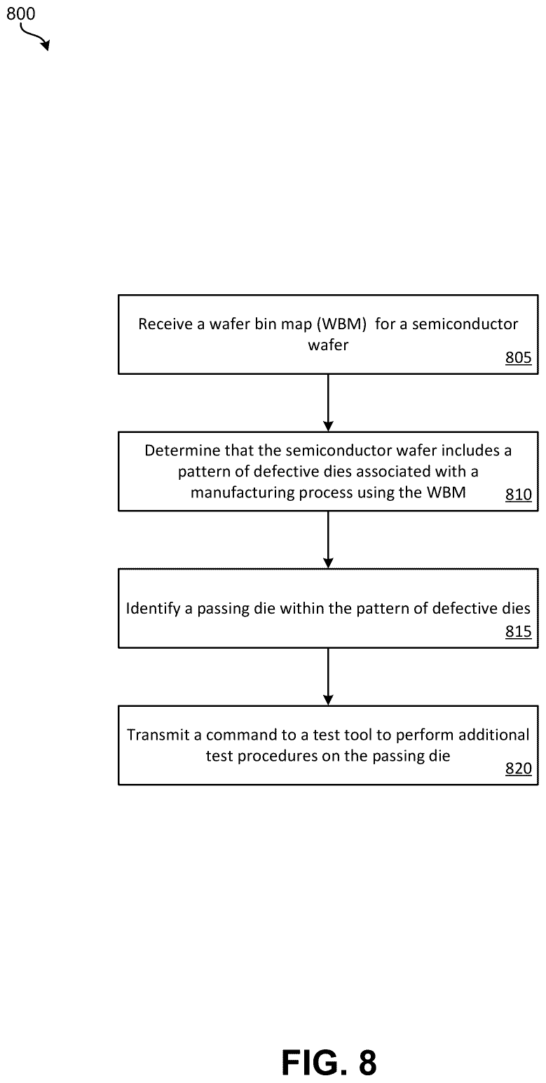

FIG. 8 illustrates an exemplary method 800 of testing electronic components according to some embodiments. Method 800 may be performed by one or more components of an automatic wafer bin map classification framework, such as processing framework 100 as described above. For example, one or more software applications executing on a central or distributed server system may perform some or all of method 800. Additionally, or alternatively, some or all of method 800 may be performed at a semiconductor manufacturing and testing facility and/or by one or more test controllers coupled with the manufacturing, testing tools, and/or binning tools used to manufacture, test, and/or bin semiconductor wafers, dies, electronic components, or the like.

At block 805, a wafer bin map for a semiconductor may be received. The wafer bin map may be the same, or include similar information, as described above in relation to block 705 of method 700. In some embodiments, the wafer bin map is received from a test tool that was used to test the semiconductor devices, or dies, fabricated on the semiconductor wafer. The wafer bin map may be received by a test controller at the manufacturing and/or testing facility where the semiconductor wafer was fabricated. Additionally, or alternatively, the wafer bin map may be received at a central processing system configured to receive wafer bin maps from a plurality of distributed manufacturing and/or testing facilities.

At block 810, a determination is made that the semiconductor wafer includes a pattern of defective dies associated with a manufacturing process. One or more blocks of method 700, described above, may be used to determine that the semiconductor wafer includes a pattern of defective dies associated with a manufacturing process. For example, one or more clustering techniques may be applied to the wafer bin map to eliminate or reduce the points in the wafer bin map that are unlikely to be associated with a defect pattern, otherwise referred to herein as noise. A set of features, including global and local features, may be extracted from the wafer bin map, the filtered bin map, and/or any distinct clusters identified in the wafer bin map using the clustering techniques. Using the set of features as an input, a trained machine learning model may be executed to generate one or more pattern classifications for the semiconductor wafer. The pattern classifications may represent individual likelihoods that the semiconductor wafer includes a respective defect pattern. Based on the determined defect pattern, one or more defects in the manufacturing process, or tools used to perform the manufacturing process, may be identified.

At block 815, a passing die within the pattern of defective dies is identified. Based on the determination that the semiconductor wafer includes a defect pattern attributable to a defective manufacturing process or tool, it may be determined that additional dies that passed an initial set of tests (e.g., passing dies) may nonetheless be of a lower quality compared to one or more predefined quality standards due to the defective manufacturing process or tool. The additional passing dies that may be of lower quality may be identified based on their location on the semiconductor wafer relative to the outer contours of the defect pattern. For example, given an edge-ring defect pattern, one or more dies that passed the initial set of tests may be identified based on their proximity to the edge of the semiconductor wafer.

At block 820, a command is transmitted to a test tool to perform additional test procedures on the passing die. The command may include a unique identifier for the passing die, such as the die's location on the semiconductor wafer, a serial number or part number assigned to the die, or the like. The command may further include an identification of the additional test procedures to be performed. For example, based on the characteristics of the manufacturing process that resulted in the defect pattern, one or more semiconductor defects and/or test results that may be affected by that particular manufacturing process may be identified. Additional tests targeting the identified defects and/or potentially affected test results may be identified and transmitted to the test tool. Method 800 may optionally include additional steps associated with rebinning the passing dies. For example, an initial binning assignment for a passing die may be updated to a binning assignment associated with failing parts and/or reduced quality parts after identifying the passing die as being located within the defect pattern.

It should be appreciated that the specific steps illustrated in FIG. 8 provide a particular method of testing electronic components according to an embodiment of the present invention. Other sequences of steps may also be performed according to alternative embodiments. For example, alternative embodiments of the present invention may perform the steps outlined above in a different order. Moreover, the individual steps illustrated in FIG. 8 may include multiple sub-steps that may be performed in various sequences as appropriate to the individual step. Furthermore, additional steps may be added or removed depending on the particular applications. One of ordinary skill in the art would recognize many variations, modifications, and alternatives.

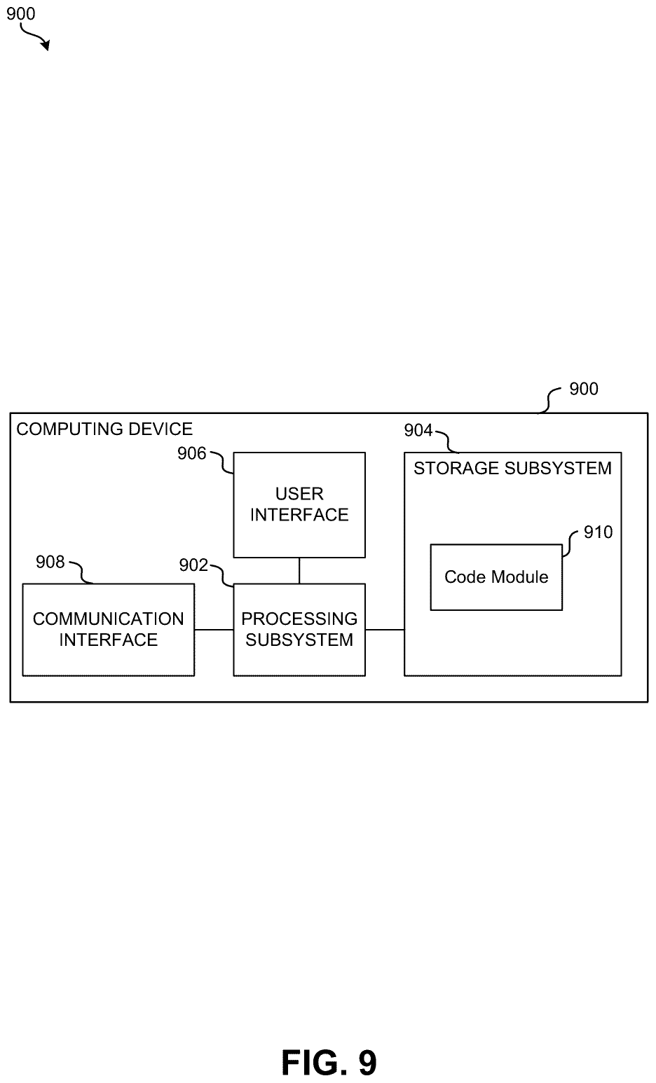

In some embodiments, one or more processing frameworks for classifying WBMs, such as framework 100, are implemented on a computing device. FIG. 9 illustrates a block diagram of an embodiment of a computing device 900. Computing device 900 can implement some or all functions, behaviors, and/or capabilities described above that would use electronic storage or processing, as well as other functions, behaviors, or capabilities not expressly described. Computing device 900 includes a processing subsystem 902, a storage subsystem 904, a user interface 906, and/or a communication interface 908. Computing device 900 can also include other components (not explicitly shown) such as a battery, power controllers, and other components operable to provide various enhanced capabilities. In various embodiments, computing device 900 can be implemented in a desktop or laptop computer, mobile device (e.g., tablet computer, smart phone, mobile phone), wearable device, media device, application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, or electronic units designed to perform a function or combination of functions described above.

Storage subsystem 904 can be implemented using a local storage and/or removable storage medium, e.g., using disk, flash memory (e.g., secure digital card, universal serial bus flash drive), or any other non-transitory storage medium, or a combination of media, and can include volatile and/or nonvolatile storage media. Local storage can include random access memory (RAM), including dynamic RAM (DRAM), static RAM (SRAM), or battery backed up RAM. In some embodiments, storage subsystem 904 can store one or more applications and/or operating system programs to be executed by processing subsystem 902, including programs to implement some or all operations described above that would be performed using a computer. For example, storage subsystem 904 can store one or more code modules 910 for implementing one or more method steps described above.

A firmware and/or software implementation may be implemented with modules (e.g., procedures, functions, and so on). A machine-readable medium tangibly embodying instructions may be used in implementing methodologies described herein. Code modules 910 (e.g., instructions stored in memory) may be implemented within a processor or external to the processor. As used herein, the term “memory” refers to a type of long term, short term, volatile, nonvolatile, or other storage medium and is not to be limited to any particular type of memory or number of memories or type of media upon which memory is stored.

Moreover, the term “storage medium” or “storage device” may represent one or more memories for storing data, including read only memory (ROM), RAM, magnetic RAM, core memory, magnetic disk storage mediums, optical storage mediums, flash memory devices and/or other machine-readable mediums for storing information. The term “machine-readable medium” includes, but is not limited to, portable or fixed storage devices, optical storage devices, wireless channels, and/or various other storage mediums capable of storing instruction(s) and/or data.

Furthermore, embodiments may be implemented by hardware, software, scripting languages, firmware, middleware, microcode, hardware description languages, and/or any combination thereof. When implemented in software, firmware, middleware, scripting language, and/or microcode, program code or code segments to perform tasks may be stored in a machine-readable medium such as a storage medium. A code segment (e.g., code module 910) or machine-executable instruction may represent a procedure, a function, a subprogram, a program, a routine, a subroutine, a module, a software package, a script, a class, or a combination of instructions, data structures, and/or program statements. A code segment may be coupled to another code segment or a hardware circuit by passing and/or receiving information, data, arguments, parameters, and/or memory contents. Information, arguments, parameters, data, etc., may be passed, forwarded, or transmitted by suitable means including memory sharing, message passing, token passing, network transmission, etc.

Implementations of the techniques, blocks, steps and means described above may be done in various ways. For example, these techniques, blocks, steps and means may be implemented in hardware, software, or a combination thereof. For a hardware implementation, the processing units may be implemented within one or more ASICs, DSPs, DSPDs, PLDs, FPGAs, processors, controllers, micro-controllers, microprocessors, other electronic units designed to perform the functions described above, and/or a combination thereof.

Each code module 910 may comprise sets of instructions (codes) embodied on a computer-readable medium that directs a processor of a computing device 900 to perform corresponding actions. The instructions may be configured to run in sequential order, in parallel (such as under different processing threads), or in a combination thereof. After loading a code module 910 on a general purpose computer system, the general purpose computer is transformed into a special purpose computer system.

Computer programs incorporating various features described herein (e.g., in one or more code modules 910) may be encoded and stored on various computer readable storage media. Computer readable media encoded with the program code may be packaged with a compatible electronic device, or the program code may be provided separately from electronic devices (e.g., via Internet download or as a separately packaged computer readable storage medium). Storage subsystem 904 can also store information useful for establishing network connections using the communication interface 908.

User interface 906 can include input devices (e.g., touch pad, touch screen, scroll wheel, click wheel, dial, button, switch, keypad, microphone, etc.), as well as output devices (e.g., video screen, indicator lights, speakers, headphone jacks, virtual- or augmented-reality display, etc.), together with supporting electronics (e.g., digital to analog or analog to digital converters, signal processors, etc.). A user can operate input devices of user interface 906 to invoke the functionality of computing device 900 and can view and/or hear output from computing device 900 via output devices of user interface 906. For some embodiments, the user interface 906 might not be present (e.g., for a process using an ASIC).

Processing subsystem 902 can be implemented as one or more processors (e.g., integrated circuits, one or more single core or multi core microprocessors, microcontrollers, central processing unit, graphics processing unit, etc.). In operation, processing subsystem 902 can control the operation of computing device 900. In some embodiments, processing subsystem 902 can execute a variety of programs in response to program code and can maintain multiple concurrently executing programs or processes. At a given time, some or all of a program code to be executed can reside in processing subsystem 902 and/or in storage media, such as storage subsystem 904. Through programming, processing subsystem 902 can provide various functionality for computing device 900. Processing subsystem 902 can also execute other programs to control other functions of computing device 900, including programs that may be stored in storage subsystem 904.

Communication interface 908 can provide voice and/or data communication capability for computing device 900. In some embodiments, communication interface 908 can include radio frequency (RF) transceiver components for accessing wireless data networks (e.g., Wi-Fi network; 3G, 4G/LTE; etc.), mobile communication technologies, components for short range wireless communication (e.g., using Bluetooth communication standards, near-field communications (NFC), etc.), other components, or combinations of technologies. In some embodiments, communication interface 908 can provide wired connectivity (e.g., universal serial bus, Ethernet, universal asynchronous receiver/transmitter, etc.) in addition to, or in lieu of, a wireless interface. Communication interface 908 can be implemented using a combination of hardware (e.g., driver circuits, antennas, modulators/demodulators, encoders/decoders, and other analog and/or digital signal processing circuits) and software components. In some embodiments, communication interface 908 can support multiple communication channels concurrently. In some embodiments, the communication interface 908 is not used.

It will be appreciated that computing device 900 is illustrative and that variations and modifications are possible. A computing device can have various functionality not specifically described (e.g., voice communication via cellular telephone networks) and can include components appropriate to such functionality.

Further, while the computing device 900 is described with reference to particular blocks, it is to be understood that these blocks are defined for convenience of description and are not intended to imply a particular physical arrangement of component parts. For example, the processing subsystem 902, the storage subsystem 904, the user interface 906, and/or the communication interface 908 can be in one device or distributed among multiple devices.

Further, the blocks need not correspond to physically distinct components. Blocks can be configured to perform various operations, e.g., by programming a processor or providing appropriate control circuitry, and various blocks might or might not be reconfigurable depending on how an initial configuration is obtained. Embodiments of the present invention can be realized in a variety of apparatus including electronic devices implemented using a combination of circuitry and software. Electronic devices described herein can be implemented using computing device 900.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method of testing semiconductor wafers, comprising:
receiving a wafer bin map for a semiconductor wafer, wherein the wafer bin map includes a plurality of points corresponding to a plurality of defective dies fabricated on the semiconductor wafer;
identifying a cluster of points in the wafer bin map from the plurality of points that correspond to a cluster of defective dies on the semiconductor wafer;
generating a filtered bin map using the cluster of points;
extracting a set of features for the filtered bin map, wherein the set of features comprises a set of global features common to the semiconductor wafer and a set of cluster features specific to the filtered bin map;
executing a trained machine learning model using the set of features as inputs to generate a pattern classification for the semiconductor wafer; and
determining, based on the pattern classification, that the semiconductor wafer includes a pattern of defective dies caused by a defective manufacturing process used to manufacture the semiconductor wafer.

2. The method of claim 1, further comprising:
executing, by a test tool, one or more component test procedures on each die of the semiconductor wafer to generate test data for each die of the semiconductor wafer;
comparing the test data for each respective die to one or more predefined test result threshold criteria to determine whether each respective die is defective; and
generating the wafer bin map for the semiconductor wafer based on the determination for each respective die.

3. The method of claim 1, wherein identifying the cluster of points comprises determining whether a distance between each point of the plurality of points and a neighboring point of the plurality of points is less than or equal to a predefined threshold distance.

4. The method of claim 1, wherein generating the filtered bin map using the cluster of points comprises excluding remaining points of the plurality of points from the filtered bin map.

5. The method of claim 1, further comprising:
identifying a subset of the plurality of points that represent noise data in the wafer bin map, wherein the filtered bin map is generated by excluding the subset of the plurality of points from wafer bin map.

6. The method of claim 1, wherein the set of global features represent at least one of: a percentage of total defective dies in the wafer bin map that are included in the filtered bin map; a total yield for the wafer bin map; or a distance from a center of the semiconductor wafer to a center of the cluster of points.

7. The method of claim 1, wherein the set of cluster features include zone features representing a number of defective dies in the filtered bin map that are located in each of a plurality of zones on the semiconductor wafer.

8. The method of claim 7, wherein the plurality of zones on the semiconductor wafer have a circular distribution.

9. The method of claim 7, wherein the plurality of zones includes a circular zone corresponding to a center of the semiconductor wafer and multiple concentric arc zones in each of four quadrants surrounding the circular zone.

10. The method of claim 1, further comprising:
identifying a point in the wafer bin map that corresponds to a passing die surrounded by the cluster of defective dies; and
transmitting a command to a test tool to execute one or more additional test procedures on the passing die based on the defective manufacturing process that caused the pattern of defective dies on the semiconductor wafer.

11. The method of claim 1, further comprising:
identifying, based on the defective manufacturing process, a manufacturing tool that performed the defective manufacturing process on the semiconductor wafer; and
causing the manufacturing tool to alter the defective manufacturing process before it fabricates a subsequent semiconductor wafer.

12. A semiconductor manufacturing system comprising:
a wafer classification system, wherein the wafer classification system comprises:
a memory; and
one or more hardware processors that, when executing computer executable instructions stored in the memory, are configured to:
receive a wafer bin map for a semiconductor wafer, wherein the wafer bin map includes a plurality of points corresponding to a plurality of defective dies fabricated on the semiconductor wafer;
identify a cluster of points in the wafer bin map from the plurality of points that correspond to a cluster of defective dies on the semiconductor wafer;
generate a filtered bin map using the cluster of points;
extract a set of features for the filtered bin map, wherein the set of features comprises a set of global features common to the semiconductor wafer and a set of cluster features specific to the filtered bin map;
execute a trained machine learning model using the set of features as inputs to generate a pattern classification for the semiconductor wafer; and
determine, based on the pattern classification, that the semiconductor wafer includes a pattern of defective dies caused by a defective manufacturing process used to manufacture the semiconductor wafer.

13. The semiconductor manufacturing system of claim 12, further comprising:
a semiconductor test tool configured to generate the wafer bin map from test data 2 collected by the semiconductor test tool in response to executing one or more semiconductor component test procedures on each die of the semiconductor wafer, wherein the wafer classification system receives the wafer bin map from the semiconductor test tool.

14. The semiconductor manufacturing system of claim 13, wherein the one or more hardware processors are further configured to:
identify a point in the wafer bin map that corresponds to a passing die surrounded by the cluster of defective dies; and
transmit a command to the semiconductor test tool to execute one or more additional test procedures on the passing die based on the defective manufacturing process that caused the pattern of defective dies on the semiconductor wafer.

15. The semiconductor manufacturing system of claim 12, further comprising a semiconductor fabrication machine configured to perform the defective manufacturing process, wherein the one or more hardware processors are further configured to:
cause the semiconductor fabrication machine to alter the defective manufacturing process before fabricating a subsequent semiconductor wafer.

16. A non-transitory processor-readable medium for testing semiconductor wafers, comprising processor-readable instructions configured to cause one or more processors of a wafer classification system to:
receive a wafer bin map for a semiconductor wafer, wherein the wafer bin map includes a plurality of points corresponding to a plurality of defective dies fabricated on the semiconductor wafer;
identify a cluster of points in the wafer bin map from the plurality of points that correspond to a cluster of defective dies on the semiconductor wafer;
generate a filtered bin map using the cluster of points;
extract a set of features for the filtered bin map, wherein the set of features comprises a set of global features common to the semiconductor wafer and a set of cluster features specific to the filtered bin map;
execute a trained machine learning model using the set of features as inputs to generate a pattern classification for the semiconductor wafer; and
determine, based on the pattern classification, that the semiconductor wafer includes a pattern of defective dies caused by a defective manufacturing process used to manufacture the semiconductor wafer.

17. The non-transitory processor-readable medium of claim 16, wherein the processor-readable instructions are further configured to cause the one or more processors of the wafer classification system to:
identify a subset of the plurality of points that represent noise data in the wafer bin map, wherein the filtered bin map is generated by excluding the subset of the plurality of points from wafer bin map.

18. The non-transitory processor-readable medium of claim 16, wherein the set of cluster features include zone features representing a number of defective dies in the filtered bin map that are located in each of a plurality of zones on the semiconductor wafer, and the plurality of zones have a circular distribution.

19. The non-transitory processor-readable medium of claim 16, wherein the processor-readable instructions are further configured to cause the one or more processors of the wafer classification system to:
identify a point in the wafer bin map that corresponds to a passing die surrounded by the cluster of defective dies; and
transmit a command to a test tool to execute one or more additional test procedures on the passing die based on the defective manufacturing process that caused the pattern of defective dies on the semiconductor wafer.

20. The non-transitory processor-readable medium of claim 16, wherein the processor-readable instructions are further configured to cause the one or more processors of the wafer classification system to:
identify, based on the defective manufacturing process, a manufacturing tool that performed the defective manufacturing process on the semiconductor wafer; and
cause the manufacturing tool to alter the defective manufacturing process before it fabricates a subsequent semiconductor wafer.
